(19) United States
(12) Patent Application Publication
(10) Pub. No.: US 2016/0004592 A1
(43) Pub. Date: Jan. 7, 2016

(54) METHOD FOR DETECTING ERROR OF DATA, STORAGE DEVICE, AND RECORDING MEDIUM

(71) Applicant: FUJITSU LIMITED, Kawasaki-shi (JP)

(72) Inventors: Toshihiko SUZUKI, Kawasaki (JP); Shinya MIYATA, Kawasaki (JP)

(73) Assignee: FUJITSU LIMITED, Kawasaki (JP)

(21) Appl. No.: 14/749,046

(22) Filed: Jun. 24, 2015

(30) Foreign Application Priority Data
Jul. 1, 2014 (JP) 2014-136032

(51) Int. Cl. G06F 11/10; H03M 13/09

(52) U.S. Cl. CPC G06F 11/1004; H03M 13/096

(57) ABSTRACT

A method includes storing, by a processor that is configured to avoid adding the error correcting code to the data when the data passes through the inside of the processor, the data received from a host device and an error correcting code in the buffer memory; reading the data from the buffer memory and transmitting the read data to a calculating circuit; calculating, by the calculating circuit, a first checksum of the data and transmitting the data to the processor; storing, by the processor, the data and the error correcting code in a sub memory; reading the data from the sub memory and transmitting the read data to the calculating circuit through the processor; calculating, by the calculating circuit, a second checksum of the data; and determining, by the processor, whether an error of the data occurs within the processor by comparing the first checksum with the second checksum.

### CROSS-REFERENCE TO RELATED APPLICATION

This application is based upon and claims the benefit of priority of the prior Japanese Patent Application No. 2014-136032, filed on Jul. 1, 2014, the entire contents of which are incorporated herein by reference.

### FIELD

The embodiment discussed herein is related to a method for detecting an error of data, a storage device, and a recording medium.

### BACKGROUND

As an adapter card serving as an interface (IF) with a host device, a storage device provided with a channel adapter (CA) is known. As related art, Japanese Laid-open Patent Publication No. 2010-191594, Japanese Laid-open Patent Publication No. 2012-88758, and Japanese Laid-open Patent Publication No. 2011-176894 are disclosed, for example.

### SUMMARY

According to an aspect of the invention, a method for detecting an error of data by a storage device including a storage configured to provide a storage region for a process by a host device and a buffer memory configured to temporarily store data that is transferred between the host device and the storage, the method includes storing, by a processor that is configured to avoid adding the error correcting code to the data when the data passes through the inside of the processor, the data received from the host device and an error correcting code in the buffer memory; reading the data from the buffer memory and transmitting the read data to a calculating circuit; calculating, by the calculating circuit, a first checksum of the data and transmitting the data to the processor; storing, by the processor, the data and the error correcting code in a sub memory; reading the data from the sub memory and transmitting the read data to the calculating circuit through the processor; calculating, by the calculating circuit, a second checksum of the data received from the sub memory and having passed through the processor; and determining, by the processor, whether an error of the data occurs within the processor by comparing the first checksum with the second checksum.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a functional configuration of a storage system;

FIG. 2 is a diagram illustrating an example of a data guarantee control process by a storage device;

FIG. 3 is an example of a sequence diagram of the data guarantee control process by the storage device;

FIG. 4 is a diagram illustrating an example of a process of making a data buffer redundant by the storage device according to a first modified example of an embodiment;

FIG. 5 is a sequence diagram of the data guarantee control process by the storage device according to the first modified example of the embodiment;

FIG. 6 is a sequence diagram of the data guarantee control process by the storage device according to the first modified example of the embodiment;

FIGS. 7A, 7B, 7C, and 7D are diagrams illustrating an example of the data guarantee control process by the storage device according to a second modified example of the embodiment;

FIG. 8 is a sequence diagram of the data guarantee control process by the storage device according to the second modified example of the embodiment;

FIG. 9 is a diagram illustrating the flow of data in a CA according to a technique related to the embodiment; and

FIG. 10 is a diagram illustrating data to be transmitted in the CA according to the technique related to the embodiment.

### DESCRIPTION OF EMBODIMENT

In a conventional CA, a part at which data is not protected by parity or the like exists. Thus, when data passes through the interested part, the data may be garbled on a bus. Since the fact that the data is garbled in the CA is not detected as an error, the erroneous data may be written in a memory device. If a part at which data is not protected by parity or the like exists, it is desirable that the identity of the data to be written in the memory device be guaranteed.

Hereinafter, an embodiment of a communication control device, a storage device, and a communication control program is described with reference to the accompanying drawings. The embodiment is merely exemplified and does not intend to exclude the application of various modified examples and techniques that are not clearly described in the embodiment. Specifically, the embodiment may be variously modified and changed without departing from the gist of the embodiment.

The drawings do not indicate only constituent elements illustrated in the drawings and may indicate that other functions and the like are included.

In the drawings, the same parts are represented by the same reference numerals and symbols, and a repetitive description thereof is omitted.

### Embodiment

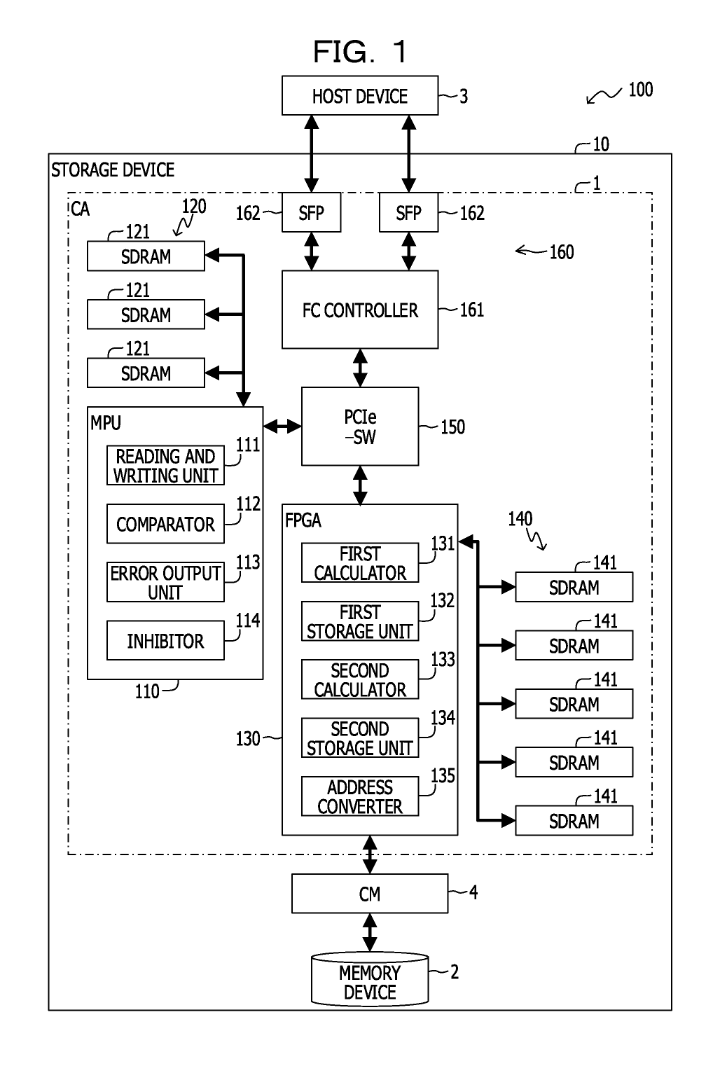

FIG. 1 is a diagram illustrating an example of a functional configuration of a storage system.

A storage system 100 provides a storage region to a host device (higher-level device) 3. The storage system 100 includes the host device 3 and a storage device 10.

The host device 3 is a computer having a server function. The host device 3 accesses the storage device 10 in order to read and write data from and in the storage device 10 in a variable length (CKD) format.

The storage device 10 has a memory device 2 (described later) and provides a storage region to the host device 3. The storage device 10 includes a CA (communication control device or communication controller) 1, the memory device 2, and a controller module (CM) 4.

The memory device 2 is a known device for storing data, while data is able to be read from and written in the memory device 2. The memory device 2 is, for example, a hard disk drive (HDD) or a solid state drive (SSD). Although the single memory device 2 is illustrated in the example of FIG. 1, the storage device 10 may include a plurality of memory devices 2. In this case, the storage device 10 may use redundant arrays of inexpensive disks (RAID) to distribute data in the plurality of memory devices 2 and store the data that is redundant.

The CM 4 is a device configured to execute control of various types. The CM 4 executes the control of the various types in accordance with a request (access control signal, hereinafter referred to as host I/O) to access the memory device 2 from the host device 3. Specifically, the CM 4 writes and reads data in and from the memory device 2 based on block access from the CA 1.

The CA 1 is an interface controller that connects the host device 3 and the memory device 2 to each other so as to enable the host device 3 and the memory device 2 to communicate with each other. The CA 1 receives data transmitted by the host device 3 or the memory device 2 and temporarily stores the data in a data buffer 140. After that, the CA 1 transfers the data to the CM 4 and transfers data received from the CM 4 to the host device 3. Specifically, the CA 1 controls input and output (I/O) of data from and to the external devices including the host device 3. The CA 1 has a function of converting variable-length access between the CA 1 and the host device 3 and block access between the CA 1 and the CM 4 into each other. In the example illustrated in FIG. 1, the CA 1 and the CM 4 are separated from each other for the description. The CA 1, however, may be installed as an interface card on the CM 4, for example.

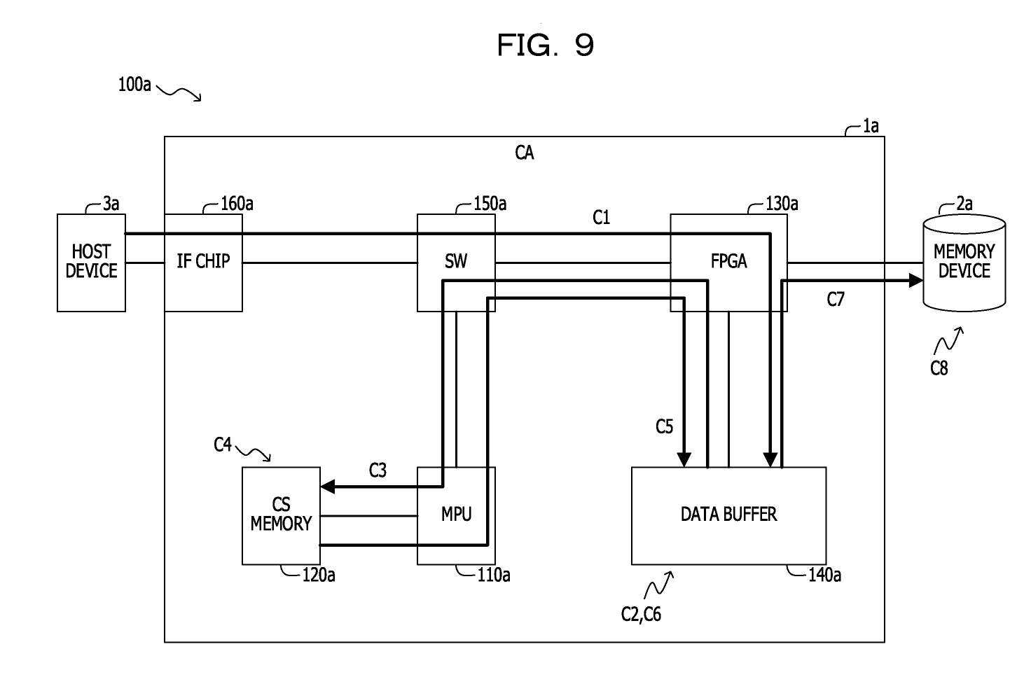

FIG. 9 is a diagram illustrating the flow of data in a CA according to a technique related to the embodiment.

A storage system 100a illustrated in FIG. 9 includes a CA la, a memory device 2a, and a host device 3a. The CA is and the memory device 2a that are included in the storage system 100a are functional configurations of a storage device (not illustrated).

The host device 3a is a computer having a server function, for example.

The memory device 2a is a known device for storing data, while data is able to be read from and written in the memory device 2a. The memory device 2a is, for example, an HDD or an SSD.

The CA is is an interface controller that connects the host device 3a and the memory device 2a to each other so as to enable the host device 3a and the memory device 2a to communicate with each other. The CA is receives data transmitted by the host device 3a and the memory device 2a and temporarily stores the data in a data buffer 140a. After that, the CA is transfers the data to a CM (not illustrated) included in the storage device and transfers data received from the CM to the host device 3a. Specifically, the CA is controls input and output (I/O) of data from and to the external devices including the host device 3a.

The CA is includes a micro-processing unit (MPU) 110a, a chip select (CS) memory 120a, a field-programmable gate array (FPGA) 130a, the data buffer 140a, a switch (SW) 150a, and an IF chip 160a.

The IF chip 160a controls a fiber channel (FC) protocol and provides two FC interfaces for the single IF chip 160a.

The SW 150a switches between a data path located between the IF chip 160a and the MPU 110a and a data path located between the MPU 110a and the FPGA 130a.

The data buffer 140a is a memory device configured to temporarily stores data that is transmitted and received between the host device 3a and the CM (not illustrated).

The FPGA 130a is an integrated circuit having a configuration that is arbitrarily settable. The FPGA 130a transmits and receives data to and from the CM (not illustrated). The FPGA 130a generates a check code and executes checking. Access between the host device 3a and the CA is is count key data (CKD) access (variable-length access), while access between the CA is and the memory device 2a is block access. The CA is has a function of converting the variable-length access and the block access into each other.

The CS memory 120a is a memory device that provides a storage region to the MPU 110a.

The MPU 110a is a processing device configured to execute control of various types and calculation of various types. The MPU 110a executes an operating system (OS) or program stored in the CS memory 120a and thereby achieves various functions.

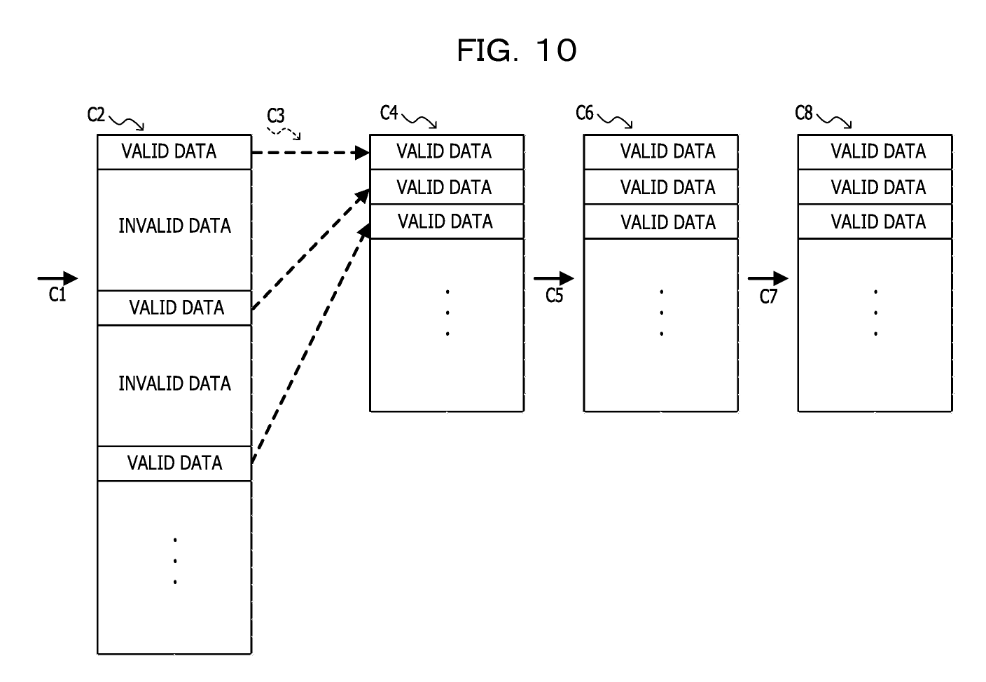

FIG. 10 is a diagram illustrating data to be transferred in the CA according to the technique related to the embodiment.

The flow of data in the storage system according to the technique related to the embodiment is described with reference to FIGS. 9 and 10. Reference symbols C1 to C8 illustrated in FIG. 9 represent the same processes as reference symbols C1 to C8 illustrated in FIG. 10.

When the host device 3a issues write I/O to the memory device 2a, data related to the write I/O is temporarily stored in the data buffer 140a (refer to reference symbol C1 illustrated in FIGS. 9 and 10). A cyclic redundancy check (CRC) code (SB2-CRC) is added to the data stored in the data buffer 140a, for example.

The data stored in the data buffer 140a includes a plurality of valid data items to be written in the memory device 2a and a plurality of invalid data items to be discarded by the MPU 110a as described later (refer to reference symbol C2 illustrated in FIGS. 9 and 10).

The MPU 110a reads the data written in the data buffer 140a and writes the read data in the CS memory 120a. In this case, the MPU 110a extracts only the valid data items from the read data, discards the invalid data items, and writes the valid data items in the CS memory 120a (refer to reference symbol C3 illustrated in FIGS. 9 and 10). End-to-end redundancy check (ECRC) is added to the data transmitted on the FPGA 130a, the SW 150a, and the bus that are located between the data buffer 140a and the MPU 110a, for example. On the other hand, ECRC is not added to data transmitted on a bus (not illustrated) within the MPU 110a installed on a path between the data buffer 140a and the CS memory 120a.

The data written in the CS memory 120a includes only the valid data items (refer to reference symbol C4 illustrated in FIGS. 9 and 10). Error checking and correction (ECC) is added to the data written in the CS memory 120a, for example.

The MPU 110a reads the data written in the CS memory 120a and causes the read data to be temporarily stored in the data buffer 140a (refer to reference symbols C5 and C6 illustrated in FIGS. 9 and 10). ECRC is added to the data transmitted on the SW 150a, the FPGA 130a, and the bus that are located between the MPU 110a and the data buffer 140a, for example. On the other hand, ECRC is not added to the data transmitted on the bus (not illustrated) within the MPU 110a installed on the path between the data buffer 140a and the CS memory 120a.

Then, the data stored in the data buffer 140a is written in the memory device 2a through the CM (not illustrated) (refer to reference symbols C7 and C8 illustrated in FIGS. 9 and 10). A field check code (FCC) and a block check code (BCC) are added to the data transmitted from the data buffer 140a, for example.

Since ECRC is not added to the data transmitted on the bus within the MPU 110a included in the CA is according to the technique related to the embodiment, the data is not protected by parity or the like and may be garbled on the bus. Since the fact that the data is garbled within the MPU 110a is not detected as an error, the erroneous data may be written in the memory device 2a. Especially, if a chain data function is used to divide data into eight or more data items, write I/O is issued, and the data is garbled on the bus within the MPU 110a, the erroneous data may be written in the memory device 2a.

On the other hand, in an example of the embodiment, as illustrated in FIG. 1, the CA 1 includes the MPU 110, a plurality (three in the example illustrated in FIG. 1) of synchronous dynamic random access memories (SDRAMs) 121, the FPGA 130, a plurality (five in the example illustrated in FIG. 1) of SDRAMs 141, peripheral components interconnect express switches (PCIe-SWs; SWs) 150, an FC controller 161, and a plurality (two in the example illustrated in FIG. 1) of small form factor pluggable modules (SFP modules) 162, for example.

The SFP modules 162 are interface modules that connect the CA 1 (storage device 10) to the host device 3 through optical fibers so as to enable the CA 1 (storage device 10) and the host device 3 to communicate with each other. The communication lines between the CA 1 (storage device 10) and the host device 3 are not limited to the optical fibers. The CA 1 may include various interface modules other than the SFP modules 162.

The FC controller 161 controls a FC protocol and provides two FC interfaces for the single FC controller 161, for example. The communication protocol between the CA 1 (storage device 10) and the host device 3 is not limited to the FC protocol. The CA 1 may include controllers that are not the FC controller 161 and support various communication protocols.

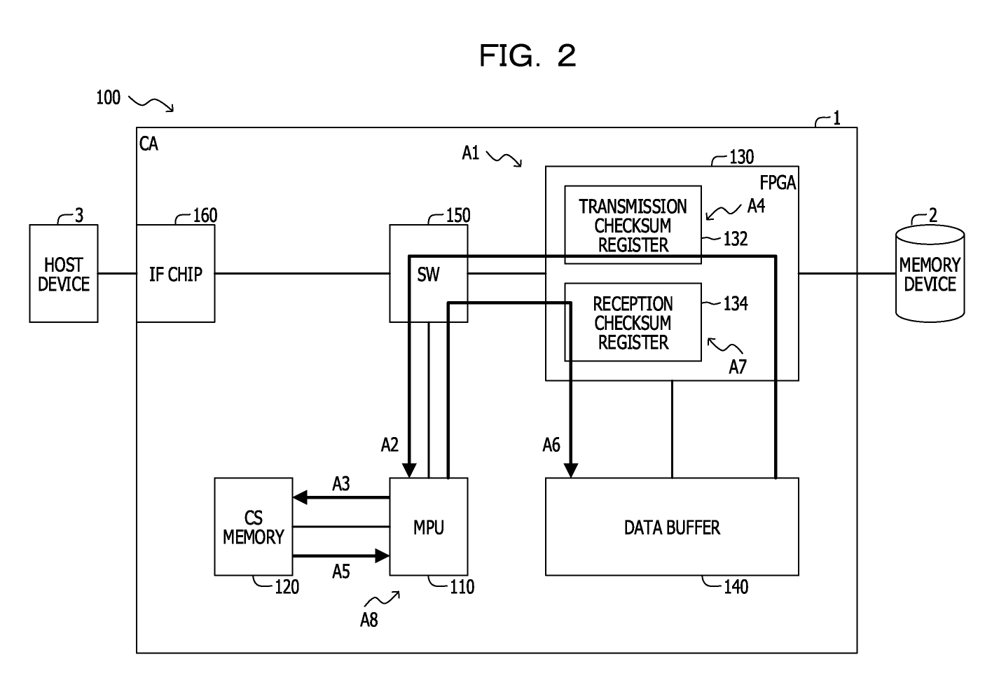

For example, the FC controller 161 and the SFP modules 162 function as the IF chip 160, as illustrated in FIG. 1 and FIG. 2 described later.

The SW 150 switches between a data path located between the FC controller 161 and the MPU 110 and a data path located between the MPU 110 and the FPGA 130. In the example of the embodiment, the SW 150 connects the FC controller 161, the MPU 110, and the FPGA 130 to each other through a PCI Express link so as to enable the FC controller 161, the MPU 110, and the FPGA 130 to communicate with each other, for example.

The SDRAMs 141 are semiconductor memories. For example, the SDRAMs 141 are double-data-rate SDRAMs (DDR SDRAMs). The SDRAMs 141 temporarily store data transmitted and to be received between the host device 3 and the CM 4. The five SDRAMs 141 illustrated in FIG. 1 function as the data buffer 140, as illustrated in FIG. 1 and FIG. 2 described later. In the example of FIG. 1, the five SDRAMs 141 are illustrated. The SDRAMs 141, however, are not limited to this. The number of SDRAMs 141 included in the CA 1 may be changed.

The FPGA 130 is an integrated circuit having a configuration that is arbitrarily settable. The FPGA 130 transmits and receives data to and from the CM 4. The FPGA 130 generates a check code and executes checking. Access between the host device 3 and the CA 1 is count key data (CKD) access (variable-length access), while access between the CA 1, the CM 4, and the memory device 2 is block access. The FPGA 130 has a function of converting the variable-length access and the block access into each other.

As illustrated in FIG. 1, the FPGA 130 functions as a first calculator 131, a first storage unit (transmission checksum register) 132, a second calculator 133, a second storage unit (reception checksum register) 134, and an address converter 135.

The first calculator 131 calculates a checksum of data transmitted from the host device 3. Specifically, when the MPU 110 reads data transmitted by the host device 3 and stored in the data buffer 140, the first calculator 131 calculates, as a transmission checksum, a checksum of the data read by the MPU 110. For example, when receiving, from the MPU 110, a request to read data stored at addresses 0x0000 to 0x0FFF of the data buffer 140, the first calculator 131 calculates the transmission checksum. The first calculator 131 causes the calculated transmission checksum to be stored in the first storage unit 132. Since the checksum may be calculated using any of known various methods, a description of the calculation method is omitted.

The first storage unit 132 is a storage region for storing a transmission checksum calculated by the first calculator 131. The first storage unit 132 is a register included in the FPGA 130.

The second calculator 133 calculates a checksum of data to be transmitted to the memory device 2. Specifically, when the MPU 110 writes data in the data buffer 140, the second calculator 133 calculates, as a reception checksum, a checksum of the data written by the MPU 110. For example, when receiving, from the MPU 110, a request to write data at the addresses 0x0000 to 0x0FFF of the data buffer 140 and addresses 0x8000 to 0x8FFF of the data buffer 140, the second calculator 133 calculates the reception checksum. The second calculator 133 causes the calculated reception checksum to be stored in the second storage unit 134.

The second storage unit 134 is a storage region for storing a reception checksum calculated by the second calculator 133. The second storage unit 134 is a register included in the FPGA 130.

The address converter 135 associates (converts) physical addresses of the data buffer 140 with (into) virtual addresses. Thus, the MPU 110 may specify the virtual addresses and read and write data from and in the data buffer 140. Details of the function of the address converter 135 are described later in a first modified example (described later) of the embodiment.

In the example of the embodiment, the FPGA 130 may not have the function as the address converter 135. In this case, the MPU 110 specifies physical addresses of the data buffer 140 and reads and writes data from and in the data buffer 140.

The SDRAMs 121 are semiconductor memories. For example, the SDRAMs 121 are DDR SDRAMs. The SDRAMs 121 provide storage regions to the MPU 110. The three SDRAMs 121 illustrated in FIG. 1 function as the CS memory 120, as illustrated in FIG. 1 and FIG. 2 described later.

The CS memory 120 stores data read by the MPU 110 from the data buffer 140. In the example of FIG. 1, the three SDRAMs 121 are illustrated. The SDRAMs 121, however, are not limited to this. The number of SDRAMs 121 included in the CA 1 may be changed.

The MPU 110 is a processing device configured to execute control of various types of control and calculation of various types. The MPU 110 executes an OS or program stored in the CS memory 120 and thereby achieves various functions such as communication with the CM 4 and control of the CA 1. Specifically, the MPU 110 functions as a reading and writing unit 111, a comparator 112, an error output unit 113, and an inhibitor 114, as illustrated in FIG. 1.

A program (communication control program) that achieves functions as the reading and writing unit 111, the comparator 112, the error output unit 113, and the inhibitor 114 is provided while being stored in a computer-readable recording medium such as a flexible disk, a CD (CD-ROM, CD-R, CD-RW, or the like), a DVD (DVD-ROM, DVD-RAM, DVD-R, DVD+R, DVD-RW, DVD+RW, HD DVD, or the like), a Blu-ray disc, a magnetic disk, an optical disc, or a magnetic optical disc. A computer reads the program through a reading device (not illustrated) from the recording medium, transfers the program to an internal or external recording device, causes the program to be stored in the internal or external recording device, and uses the program. The program may be stored in a memory device (recording medium) such as a magnetic disk, an optical disc, or a magnetic optical disc and provided to the computer from the memory device through a communication path.

In order to achieve the functions as the reading and writing unit 111, the comparator 112, the error output unit 113, and the inhibitor 114, the program stored in the internal memory device (CS memory 120 in the embodiment) is executed by a microprocessor (MPU 110 in the embodiment) of the computer. In this case, the program stored in the recording medium may be read and executed by the computer.

The reading and writing unit 111 reads and writes data from and in the CS memory 120, the first storage unit 132, the second storage unit 134, and the data buffer 140.

Specifically, the reading and writing unit 111 reads data stored in the data buffer 140 and causes the read data to be stored in the CS memory 120.

The reading and writing unit 111 reads data written in the CS memory 120 and causes the read data to be stored in the data buffer 140.

The reading and writing unit 111 reads, from the first storage unit 132, a transmission checksum calculated by the first calculator 131 of the FPGA 130. Then, the reading and writing unit 111 reads, from the second storage unit 134, a reception checksum calculated by the second calculator 133 of the FPGA 130. When the reading and writing unit 111 reads data stored in the data buffer 140, the reading and writing unit 111 clears values stored in the first and second storage units 132 and 134 of the FPGA 130 to “0”.

The comparator 112 compares the transmission checksum read by the reading and writing unit 111 with the reception checksum read by the reading and writing unit 111. Specifically, the comparator 112 determines whether or not the transmission checksum stored in the first storage unit 132 matches the reception checksum stored in the second storage unit 134.

If the transmission checksum does not match the reception checksum as a result of the comparison made by the comparator 112, the error output unit 113 outputs an error. For example, if the comparator 112 determines that the transmission checksum does not match the reception checksum, the error output unit 113 outputs the error to a display device (not illustrated). Thus, the error output unit 113 notifies a user that an error such as garbling of data to be written in the memory device 2 by I/O provided by the host device 3 occurs.

If the transmission checksum does not match the reception checksum as a result of the comparison made by the comparator 112, the inhibitor 114 inhibits the data from being transmitted to the memory device 2. For example, if the comparator 112 determines that the transmission checksum does not match the reception checksum, the inhibitor 114 issues an inhibition signal to the CM 4 and thereby inhibits the data stored in the data buffer 140 from being written in the memory device 2. Thus, the inhibitor 114 inhibits data that may be garbled in the MPU 110 from being written in the memory device 2.

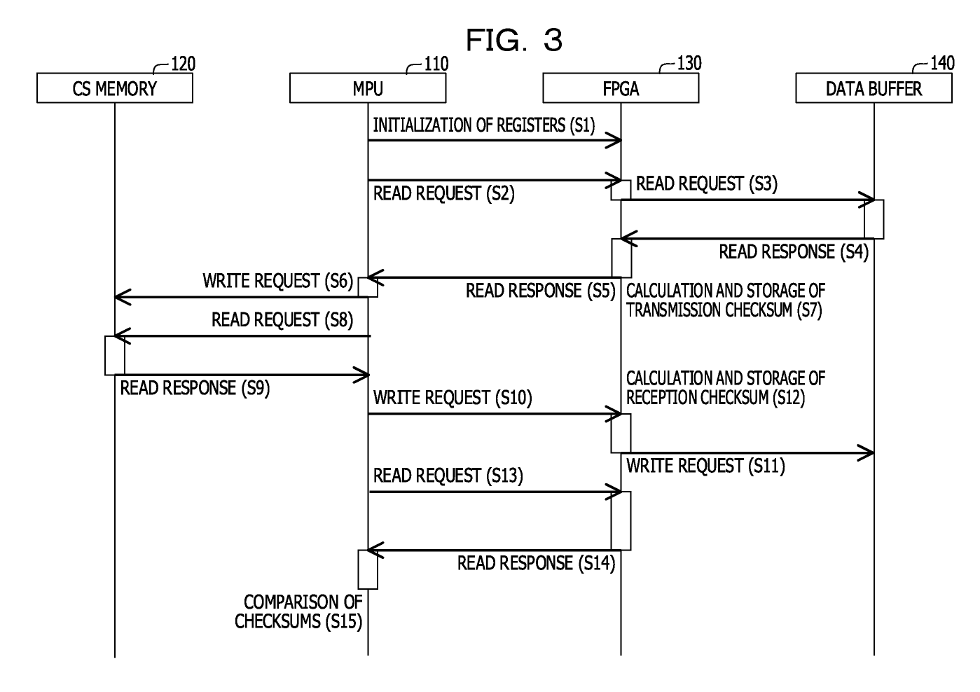

A data guarantee control process by the storage device according to the embodiment is described with reference to FIG. 2 and FIG. 3 that is an example of a sequence diagram (S1 to S15).

FIG. 2 is a diagram illustrating an example of the data guarantee control process by the storage device. FIG. 3 is the example of the sequence diagram of the data guarantee control process by the storage device.

In the example illustrated in FIG. 2, a housing of the storage device 10 and the CM 4 included in the storage device 10 are omitted in order to simplify the illustration. In FIG. 2, only the transmission checksum register 132 and the reception checksum register 134 are illustrated as functional configurations included in the FPGA 130, and the other functional configurations are omitted in order to simplify the illustration.

When I/O is issued by the host device 3 and data is stored in the data buffer 140, the reading and writing unit 111 of the MPU 110 clears (initializes) values stored in the transmission checksum register 132 and reception checksum register 134 to “0” (refer to reference symbol A1 illustrated in FIGS. 2 and S1 illustrated in FIG. 3).

The reading and writing unit 111 reads the data stored in the data buffer 140 (refer to reference symbol A2 illustrated in FIG. 2). Specifically, the reading and writing unit 111 issues, to the FPGA 130, a request to read the data stored (at, for example, addresses 0x0000 to 0x0100) in the data buffer 140 (refer to S2 illustrated in FIG. 3). The FPGA 130 transfers the read request issued by the MPU 110 to the data buffer 140 (refer to S3 illustrated in FIG. 3). The data buffer 140 issues a read response to the FPGA 130 (refer to S4 illustrated in FIG. 3). Then, the FPGA 130 transfers the read response received from the data buffer 140 to the MPU 110 (refer to S5 illustrated in FIG. 3).

The reading and writing unit 111 of the MPU 110 writes the data read from the data buffer 140 in the CS memory 120 (refer to reference symbol A3 illustrated in FIG. 2). In other words, the reading and writing unit 111 issues a request to write the data to the CS memory 120 (refer to S6 illustrated in FIG. 3).

The first calculator 131 of the FPGA 130 calculates a checksum of the data read by the MPU 110 from the data buffer 140. Then, the first calculator 131 causes the calculated checksum to be stored as a transmission checksum in the transmission checksum register 132 (refer to reference symbol A4 illustrated in FIGS. 2 and S7 illustrated in FIG. 3).

The reading and writing unit 111 of the MPU 110 reads the data written in the CS memory 120 (refer to reference symbol A5 illustrated in FIG. 2). Specifically, the reading and writing unit 111 issues a request to read the data to the CS memory 120 (refer to S8 illustrated in FIG. 3). Then, the CS memory 120 issues a response to the reading of the data to the MPU 110 (refer to S9 illustrated in FIG. 3).

The reading and writing unit 111 of the MPU 110 writes the data read from the CS memory 120 in the data buffer 140 (refer to reference symbol A6 illustrated in FIG. 2). Specifically, the reading and writing unit 111 issues, to the FPGA 130, a request to write the data (at, for example, the addresses 0x0000 to 0x0100) in the data buffer 140 (refer to S10 illustrated in FIG. 3). The FPGA 130 transfers the write request received from the MPU 110 to the data buffer 140 (refer to S11 illustrated in FIG. 3).

The second calculator 133 of the FPGA 130 calculates a checksum of the data written by the MPU 110 in the data buffer 140. Then, the second calculator 133 causes the calculated checksum to be stored as a reception checksum in the reception checksum register 134 (refer to reference symbol A7 illustrated in FIGS. 2 and S12 illustrated in FIG. 3).

The reading and writing unit 111 of the MPU 110 reads the transmission checksum stored in the transmission checksum register 132 and the reception checksum stored in the reception checksum register 134. Specifically, the reading and writing unit 111 issues a request to read the transmission checksum and the reception checksum to the FPGA 130 (refer to S13 illustrated in FIG. 3). Then, the FPGA 130 issues, to the MPU 110, a response to the reading of the transmission checksum and the reception checksum (refer to S14 illustrated in FIG. 3).

The comparator 112 of the MPU 110 compares the transmission checksum read by the reading and writing unit 111 with the reception checksum read by the reading and writing unit 111 (refer to reference symbol A8 illustrated in FIGS. 2 and S15 illustrated in FIG. 3).

If the transmission checksum matches the reception checksum as a result of the comparison made by the comparator 112, the data stored in the data buffer 140 is transmitted to the memory device 2.

On the other hand, if the transmission checksum does not match the reception checksum as a result of the comparison made by the comparator 112, the error output unit 113 of the MPU 110 outputs an error. If the transmission checksum does not match the reception checksum as a result of the comparison made by the comparator 112, the inhibitor 114 of the MPU 110 may inhibit the data from being transmitted to the memory device 2.

The communication control device 1 (storage device 10) according to the aforementioned example of the embodiment may provide the following effects, for example.

The first calculator 131 calculates a first value related to data read by the reading and writing unit 111 from the data storage unit 140. The second calculator 133 calculates a second value related to data written by the reading and writing unit 111 in the data storage unit 140. Then, the comparator 112 compares the first value stored in the first storage unit 132 with the second value stored in the second storage unit 134. The identity of the data to be written in the memory device 2 may be guaranteed by the comparison made by the comparator 112.

The error output unit 113 outputs an error if the first value does not match the second value as a result of the comparison made by the comparator 112. Thus, the user may know that an error such as garbling of data to be written in the memory device 2 occurs.

If the first value does not match the second value as a result of the comparison made by the comparator 112, the inhibitor 114 inhibits the data from being transmitted to the memory device 2. It is, therefore, possible to inhibit data within the memory device 2 from being damaged by the writing of erroneous data such as garbled data in the memory device 2.

Since a function of protecting data on the internal bus of the MPU 110 is not provided, it is possible to inhibit a manufacturing cost from increasing due to an increase in the size of a circuit.

In addition, since the protection of data on the internal bus of the MPU 110 is not provided, it is possible to inhibit performance such as a rate of transferring data from being reduced.

### FIRST MODIFIED EXAMPLE

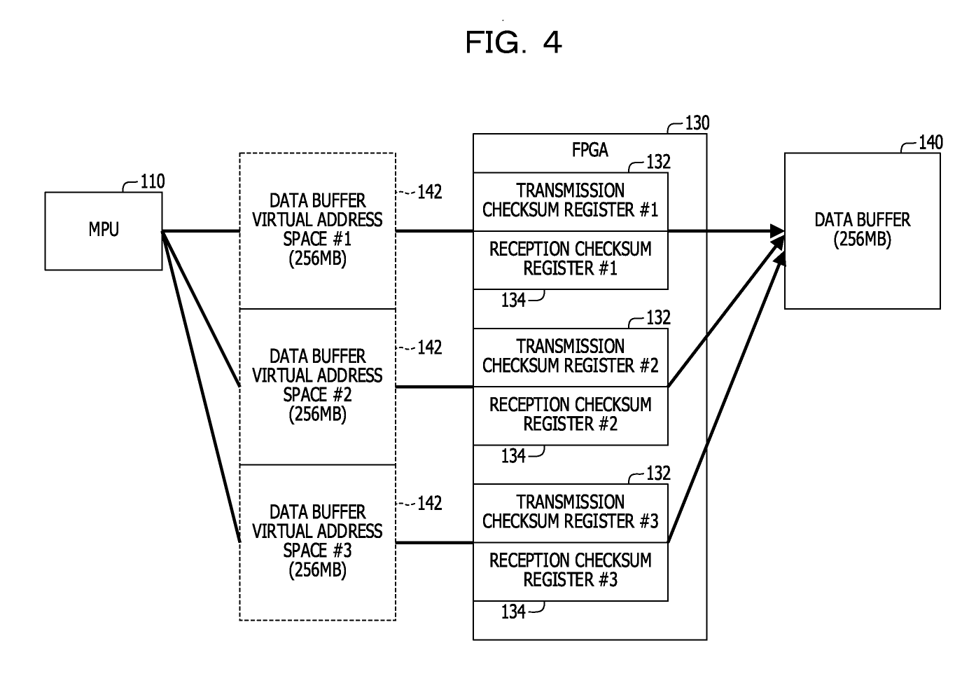

FIG. 4 is a diagram illustrating an example of a process of making the data buffer redundant by the storage device according to a first modified example of the embodiment.

In the example of FIG. 4, only multiple pairs of transmission checksum registers 132 and reception checksum registers 134 are illustrated as functional configurations included in the FPGA 130. In the example of FIG. 4, the other functional configurations are omitted in order to simplify the illustration.

In the first modified example of the embodiment, the data guarantee control process is made redundant and executed.

The address converter 135 of the FPGA 130 associates (converts) physical addresses of the data buffer 140 with (into) redundant virtual addresses. In the example illustrated in FIG. 4, the address converter 135 associates the physical addresses of the data buffers 140 with three-times redundant virtual address spaces.

Specifically, the address converter 135 defines three storage regions within the data buffer 140. The address converter 135 sets data buffer virtual address spaces 142 corresponding to the three storage regions.

The FPGA 130 includes the multiple pairs of transmission checksum registers 132 and reception checksum registers 134, while the pairs correspond to the virtual address spaces made redundant by the address converter 135. In the example illustrated in FIG. 4, the FPGA 130 includes the three pairs of transmission checksum registers 132 (transmission checksum registers #1 to #3) and reception checksum registers 134 (reception checksum registers #1 to #3), while the number of the pairs is equal to the number of the redundant virtual address spaces.

Hereinafter, when one of the transmission checksum registers is to be identified, the transmission checksum register is represented as the “transmission checksum register #1”, the “transmission checksum register #2”, or the “transmission checksum register #3”. However, when any of the transmission checksum registers is to be identified, the transmission checksum register is represented as a “transmission checksum register 132”. Hereinafter, when one of the reception checksum registers is to be identified, the reception checksum register is represented as the “reception checksum register #1”, the “reception checksum register #2”, or the “reception checksum register #3”. However, when any of the reception checksum registers is to be identified, the reception checksum register is represented as a “reception checksum register 134”.

The reading and writing unit 111 of the MPU 110 sets a memory map (not illustrated) stored in, for example, the SDRAM 121 so as to ensure that the set memory map is able to be referenced. Then, the reading and writing unit 111 references the stored memory map and thereby recognizes the data buffer virtual address spaces 142 obtained by making a physical address space of the data buffer 140 redundant. In the example illustrated in FIG. 4, the reading and writing unit 111 recognizes the virtual address spaces of the data buffer 140 as the three data buffer virtual address spaces 142 (data buffer virtual address spaces #1 to #3).

Hereinafter, when one of the data buffer virtual address spaces is to be identified, the data buffer virtual address space is represented as the “data buffer virtual address space #1”, the “data buffer virtual address space #2”, or the “data buffer virtual address space #3”. However, when any of the data buffer virtual address spaces is to be identified, the data buffer virtual address space is represented as a “data buffer virtual address space 142”.

A data capacity (of 256 MB in the example illustrated in FIG. 4) that is equal to the physical address space of the data buffer 140 is defined for each of the data buffer virtual address spaces #1 to #3. Thus, the reading and writing unit 111 of the MPU 110 recognizes the data buffer virtual address spaces 142 obtained by expanding the physical address space of the data buffer 140 threefold. The reading and writing unit 111 specifies virtual addresses (data buffer virtual address spaces 142) and thereby reads and writes data from and in the data buffer 140.

In the example illustrated in FIG. 4, the transmission checksum register #1 and the reception checksum register #1 are associated with the data buffer virtual address space #1. The transmission checksum register #2 and the reception checksum register #2 are associated with the data buffer virtual address space #2. The transmission checksum register #3 and the reception checksum register #3 are associated with the data buffer virtual address space #3.

In the first modified example of the embodiment, data to be read and written by the reading and writing unit 111 of the MPU 110 from and in the data buffer virtual address spaces #1 to #3 specified by the reading and writing unit 111 is represented as data #1 to #3 in some cases. In the first modified example of the embodiment, transmission checksums stored in the transmission checksum registers #1 to #3 are represented as transmission checksums #1 to #3 in some cases, and reception checksums stored in the reception checksum registers #1 to #3 are represented as reception checksums #1 to #3 in some cases.

The first calculator 131 and second calculator 133 of the FPGA 130 cause a transmission checksum and reception checksum calculated for the same data to be stored in a single pair of a transmission checksum register 132 and a reception checksum register 134.

Specifically, when the MPU 110 reads the data #1 from the data buffer virtual address space #1 specified by the MPU 110, the first calculator 131 calculates the transmission checksum #1 and causes the calculated transmission checksum #1 to be stored in the transmission checksum register #1. When the MPU 110 writes the data #1 in the data buffer virtual address space #1 specified by the MPU 110, the second calculator 133 calculates the reception checksum #1 and causes the calculated reception checksum #1 to be stored in the reception checksum register #1.

When the MPU 110 reads the data #2 from the data buffer virtual address space #2 specified by the MPU 110, the first calculator 131 calculates the transmission checksum #2 and causes the calculated transmission checksum #2 to be stored in the transmission checksum register #2. When the MPU 110 writes the data #2 in the data buffer virtual address space #2 specified by the MPU 110, the second calculator 133 calculates the reception checksum #2 and causes the calculated reception checksum #2 to be stored in the reception checksum register #2.

When the MPU 110 reads the data #3 from the data buffer virtual address space #3 specified by the MPU 110, the first calculator 131 calculates the transmission checksum #3 and causes the calculated transmission checksum #3 to be stored in the transmission checksum register #3. When the MPU 110 writes the data #3 in the data buffer virtual address space #3 specified by the MPU 110, the second calculator 133 calculates the reception checksum #3 and causes the calculated reception checksum #3 to be stored in the reception checksum register #3.

The comparator 112 of the MPU 110 compares a transmission checksum with a reception checksum for each of the pairs of transmission checksum registers 132 and reception checksum registers 134.

Specifically, the comparator 112 compares the transmission checksum #1 stored in the transmission checksum register #1 with the reception checksum #1 stored in the reception checksum register #1. The comparator 112 compares the transmission checksum #2 stored in the transmission checksum register #2 with the reception checksum #2 stored in the reception checksum register #2. The comparator 112 compares the transmission checksum #3 stored in the transmission checksum register #3 with the reception checksum #3 stored in the reception checksum register #3.

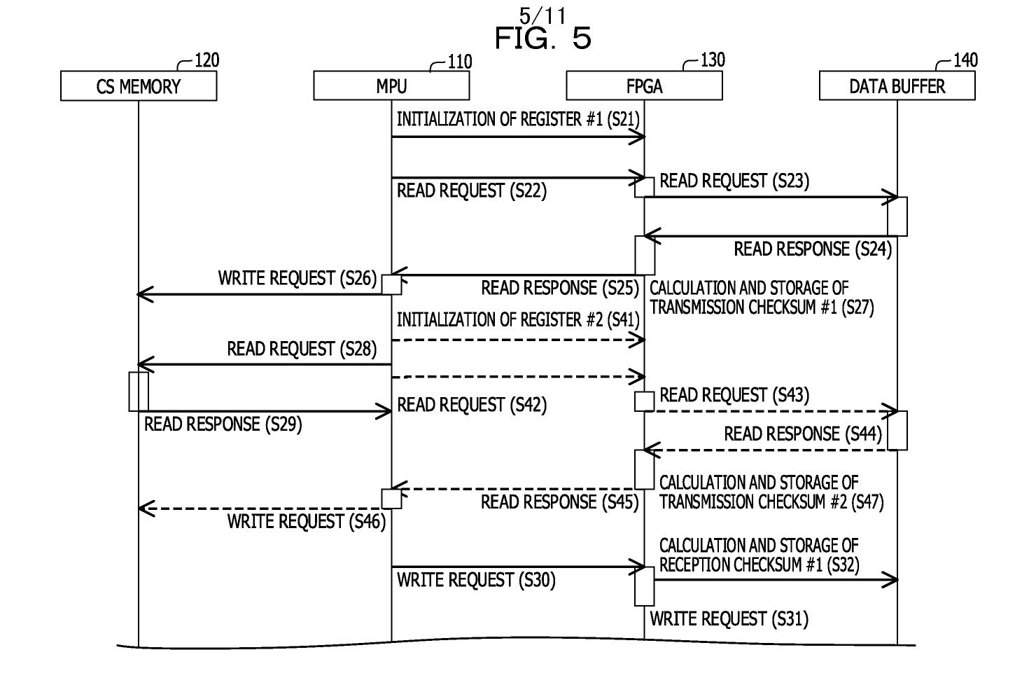

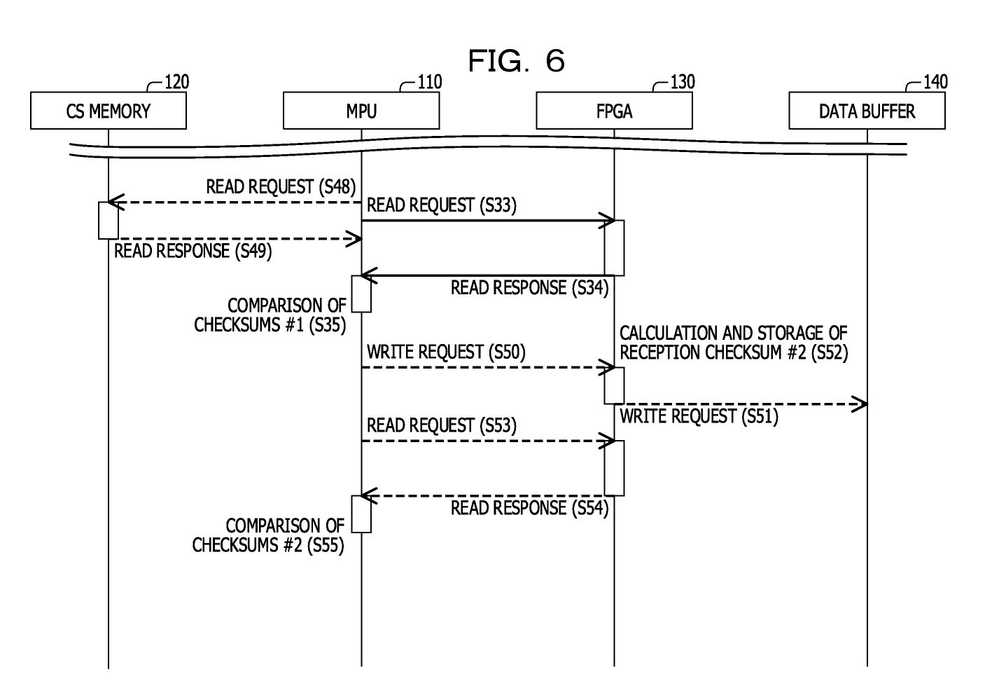

An example of the data guarantee control process by the storage device according to the first modified example of the embodiment is described with reference to sequence diagrams (S21 to S35 and S41 to S55) of FIGS. 5 and 6. FIGS. 5 and 6 are the sequence diagrams of the data guarantee control process by the storage device according to the first modified example of the embodiment. Specifically, FIG. 5 illustrates S21 to S32 and S41 to S47, and FIG. 6 illustrates S33 to S35 and S48 to S55.

In the example illustrated in FIGS. 5 and 6, the reading and writing unit 111 of the MPU 110 specifies the data buffer virtual address spaces #1 and #2 and reads and writes the data #1 and #2 from and in the data buffer virtual address spaces #1 and #2. S21 to S35 indicated by solid lines in FIGS. 5 and 6 represent processes related to the data #1. S41 to S55 indicated by broken lines in FIGS. 5 and 6 represent processes related to the data #2.

When I/O is issued by the host device 3 and the data #1 is stored in the data buffer 140, the reading and writing unit 111 of the MPU 110 clears (initializes) values stored in the transmission checksum register #1 and reception checksum register #1 to “0” (refer to S21 illustrated in FIG. 5).

The reading and writing unit 111 reads the data #1 stored in the data buffer 140. Specifically, the reading and writing unit 111 specifies the data buffer virtual address space #1 and issues, to the FPGA 130, a request to read the data #1 stored (at, for example, the addresses 0x0000 to 0x0100) in the data buffer 140 (refer to S22 illustrated in FIG. 5). The address converter 135 of the FPGA 130 converts virtual addresses corresponding to the read request issued by the MPU 110 into the physical addresses and transfers the read request to the data buffer 140 (refer to S23 illustrated in FIG. 5). The data buffer 140 issues a read response to the FPGA 130 (refer to S24 illustrated in FIG. 5). Then, the address converter 135 of the FPGA 130 converts the physical addresses corresponding to the read response issued by the data buffer 140 into the virtual addresses and transfers the read response to the MPU 110 (refer to S25 illustrated in FIG. 5).

The reading and writing unit 111 of the MPU 110 issues a request to write the data #1 to the CS memory 120 and writes the read data #1 in the CS memory 120 (refer to S26 illustrated in FIG. 5).

The first calculator 131 of the FPGA 130 calculates a checksum of the data #1 read by the MPU 110 from the data buffer 140 and causes the calculated checksum to be stored as the transmission checksum #1 in the transmission checksum register #1 (refer to S27 illustrated in FIG. 5).

When I/O is issued by the host device 3 and the data #2 is stored in the data buffer 140, the reading and writing unit 111 of the MPU 110 clears (initializes) values stored in the transmission checksum register #2 and reception checksum register #2 to “0” (refer to S41 illustrated in FIG. 5).

The reading and writing unit 111 reads the data #1 written in the CS memory 120. Specifically, the reading and writing unit 111 issues a request to read the data #1 to the CS memory 120 (refer to S28 illustrated in FIG. 5). Then, the CS memory 120 issues a response to the reading of the data #1 to the MPU 110 (refer to S29 illustrated in FIG. 5).

The reading and writing unit 111 reads the data #2 stored in the data buffer 140. Specifically, the reading and writing unit 111 specifies the data buffer virtual address space #2 and issues a request to read the data #2 stored (at, for example, addresses 0x1100 to 0x1200) in the data buffer 140 to the FPGA 130 (refer to S42 illustrated in FIG. 5). The address converter 135 of the FPGA 130 converts virtual addresses corresponding to the read request issued by the MPU 110 into the physical addresses and transfers the read request to the data buffer 140 (refer to S43 illustrated in FIG. 5). The data buffer 140 issues a read response to the FPGA 130 (refer to S44 illustrated in FIG. 5). Then, the address converter 135 of the FPGA 130 converts the physical addresses corresponding to the read response issued by the data buffer 140 into the virtual addresses and transfers the read response to the MPU 110 (refer to S45 illustrated in FIG. 5).

The reading and writing unit 111 of the MPU 110 issues a request to write the data #2 to the CS memory 120 and writes the read data #2 in the CS memory 120 (refer to S46 illustrated in FIG. 5).

The first calculator 131 of the FPGA 130 calculates a checksum of the data #2 read by the MPU 110 from the data buffer 140. Then, the first calculator 131 causes the calculated checksum to be stored as the transmission checksum #2 in the transmission checksum register #2 (refer to S47 illustrated in FIG. 5).

The reading and writing unit 111 of the MPU 110 writes the data #1 read from the CS memory 120 in the data buffer 140. Specifically, the reading and writing unit 111 specifies the data buffer virtual address space #1 and issues, to the FPGA 130, a request to write the data #1 (at, for example, the addresses 0x0000 to 0x0100) in the data buffer 140 (refer to S30 illustrated in FIG. 5). The address converter 135 of the FPGA 130 converts virtual addresses corresponding to the write request issued by the MPU 110 into the physical addresses and transfers the write request to the data buffer 140 (refer to S31 illustrated in FIG. 5).

The second calculator 133 of the FPGA 130 calculates a checksum of the data #1 written by the MPU 110 in the data buffer 140. Then, the second calculator 133 causes the calculated checksum to be stored as the reception checksum #1 in the reception checksum register #1 (refer to S32 illustrated in FIG. 5).

The reading and writing unit 111 of the MPU 110 reads the data #2 written in the CS memory 120. Specifically, the reading and writing unit 111 issues a request to read the data #2 to the CS memory 120 (refer to S48 illustrated in FIG. 6). Then, the CS memory 120 issues a response to the reading of the data #2 to the MPU 110 (refer to S49 illustrated in FIG. 6).

The reading and writing unit 111 of the MPU 110 reads the transmission checksum #1 stored in the transmission checksum register #1 and the reception checksum #1 stored in the reception checksum register #1. Specifically, the reading and writing unit 111 issues a request to read the transmission checksum #1 and the reception checksum #1 to the FPGA 130 (refer to S33 illustrated in FIG. 6). Then, the FPGA 130 issues a response to the reading of the transmission checksum #1 and the reception checksum #1 to the MPU 110 (refer to S34 illustrated in FIG. 6).

The comparator 112 of the MPU 110 compares the transmission checksum #1 read by the reading and writing unit 111 with the reception checksum #1 read by the reading and writing unit 111 (refer to S35 illustrated in FIG. 6).

If the transmission checksum #1 matches the reception checksum #1 as a result of the comparison made by the comparator 112, the data #1 stored in the data buffer 140 is transmitted to the memory device 2.

On the other hand, if the transmission checksum #1 does not match the reception checksum #1 as a result of the comparison made by the comparator 112, the error output unit 113 of the MPU 110 outputs an error. If the transmission checksum #1 does not match the reception checksum #1 as a result of the comparison made by the comparator 112, the inhibitor 114 of the MPU 110 may inhibit the data #1 from being transmitted to the memory device 2.

The reading and writing unit 111 of the MPU 110 writes the data #2 read from the CS memory 120 in the data buffer 140. Specifically, the reading and writing unit 111 specifies the data buffer virtual address space #2 and issues a request to write the data #2 (at, for example, the addresses 0x1100 to 0x1200) in the data buffer 140 to the FPGA 130 (refer to S50 illustrated in FIG. 6). The address converter 135 of the FPGA 130 converts virtual addresses corresponding to the write request issued by the MPU 110 into the physical addresses and transfers the write request to the data buffer 140 (refer to S51 illustrated in FIG. 6).

The second calculator 133 of the FPGA 130 calculates a checksum of the data #2 written by the MPU 110 in the data buffer 140. Then, the second calculator 133 causes the calculated checksum to be stored as the reception checksum #2 in the reception checksum register #2 (refer to S52 illustrated in FIG. 6).

The reading and writing unit 111 of the MPU 110 reads the transmission checksum #2 stored in the transmission checksum register #2 and the reception checksum #2 stored in the reception checksum register #2. Specifically, the reading and writing unit 111 issues a request to read the transmission checksum #2 and the reception checksum #2 to the FPGA 130 (refer to S53 illustrated in FIG. 6). Then, the FPGA 130 issues a response to the reading of the transmission checksum #2 and the reception checksum #2 to the MPU 110 (refer to S54 illustrated in FIG. 6).

The comparator 112 of the MPU 110 compares the transmission checksum #2 read by the reading and writing unit 111 with the reception checksum #2 read by the reading and writing unit 111 (refer to S55 illustrated in FIG. 6).

If the transmission checksum #2 matches the reception checksum #2 as a result of the comparison made by the comparator 112, the data #2 stored in the data buffer 140 is transmitted to the memory device 2.

On the other hand, if the transmission checksum #2 does not match the reception checksum #2 as a result of the comparison made by the comparator 112, the error output unit 113 of the MPU 110 outputs an error. If the transmission checksum #2 does not match the reception checksum #2 as a result of the comparison made by the comparator 112, the inhibitor 114 of the MPU 110 may inhibit the data #2 from being transmitted to the memory device 2.

The communication control device 1 (storage device 10) according to the first modified example of the embodiment may provide the effects described above in the example of the embodiment and the following effects, for example.

The address converter 135 associates physical addresses of the data storage unit 140 with redundant virtual addresses. Then, the reading and writing unit 111 specifies virtual addresses and reads and writes data from and in the data storage unit 140. Thus, when I/O is made redundant and issued by the higher-level device 3, processes of transferring a plurality of data items may be made redundant and executed in parallel.

The comparator 112 makes a comparison for each of the pairs of first and second storage units 132 and 134 corresponding to redundant virtual address spaces. Thus, when I/O is made redundant and issued by the higher-level device 3, the data guarantee control process may be made redundant and executed on a plurality of data items in parallel.

### SECOND MODIFIED EXAMPLE

As described with reference to FIGS. 9 and 10, data to be transferred in the storage system according to the technique related to the embodiment may include valid data to be written in the memory device 2a and invalid data to be discarded by the MPU 110a. In this case, the MPU 110a extracts only the valid data from the data read from the data buffer 140a, discards the invalid data, and writes the valid data in the data buffer 140a after the discarding of the invalid data.

In the aforementioned example of the embodiment, if data transmitted by the host device 3 includes invalid data, a value of a transmission checksum calculated by the first calculator 131 of the FPGA 130 before the discarding of the invalid data is different from a value of a reception checksum calculated by the second calculator 133 of the FPGA 130 after the discarding of the invalid data. Thus, regardless of the fact that an error such as garbling of the data on the bus within the MPU 110 does not occur, the comparator 112 of the MPU 110 detects that the transmission checksum does not match the reception checksum.

In the second modified example of the embodiment, even if data transmitted by the host device 3 includes invalid data, the reading and writing unit 111 of the MPU 110 writes the invalid data as dummy data in the FPGA 130. For example, a data buffer virtual address space for dummy writing is defined, as well as the data buffer virtual address spaces #1 to #3 illustrated in FIG. 4. The reading and writing unit 111 specifies the data buffer virtual address space for dummy writing and writes the dummy data in a reception buffer (not illustrated) included in the FPGA 130 (hereinafter, the writing of the dummy data in the reception buffer included in the FPGA 130 is referred to as “the writing of the dummy data in the FPGA 130” in some cases). For example, physical addresses corresponding to a data buffer virtual address space 142 are defined as 0x0000 to 0x0FFF, while physical addresses corresponding to the data buffer virtual address space for dummy writing are defined as 0x8000 to 0x8FFF.

The data buffer virtual address space for dummy writing is specified and the dummy data written in the data buffer virtual address space for dummy writing is set so as not to be written in the data buffer 140. For example, when receiving a request to write data at the addresses 0x0000 to 0x0FFF of the data buffer 140 from the MPU 110, the address converter 135 of the FPGA 130 writes the data corresponding to the write request in the data buffer 140. When receiving a request to write data at the addresses 0x8000 to 0x8FFF of the data buffer 140 from the MPU 110, the address converter 135 does not write the data corresponding to the write request in the data buffer 140.

The second calculator 133 of the FPGA 130 calculates a reception checksum based on data (valid data) written by the MPU 110 in the data buffer 140 and the dummy data (invalid data) written by the MPU 110 in the FPGA 130.

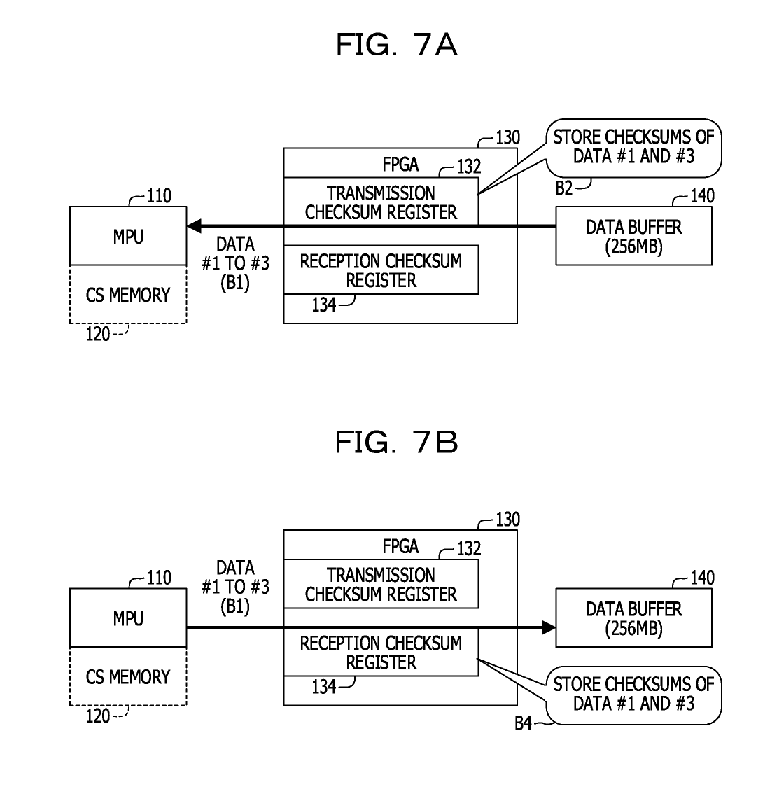

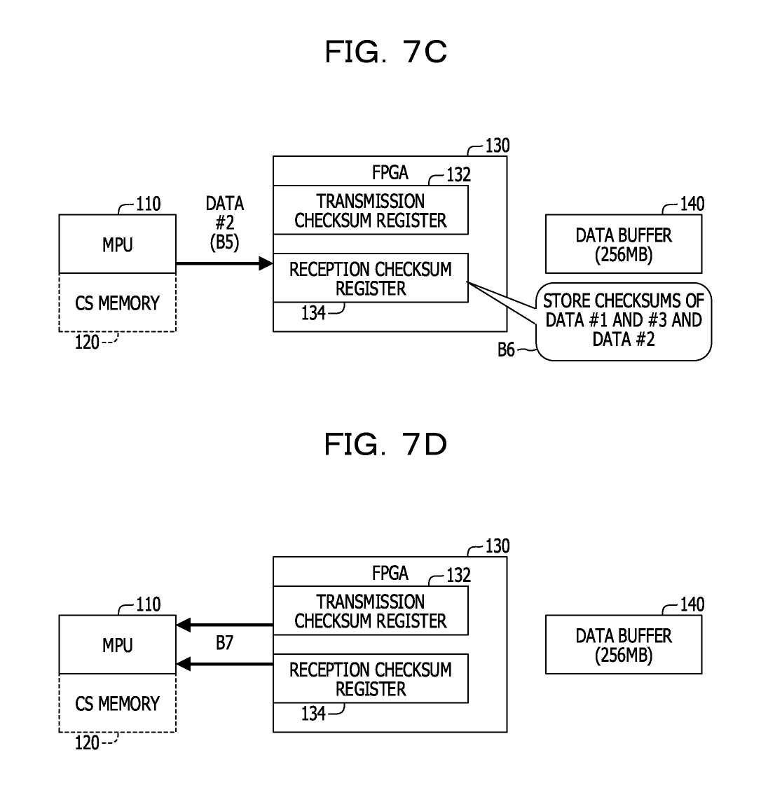

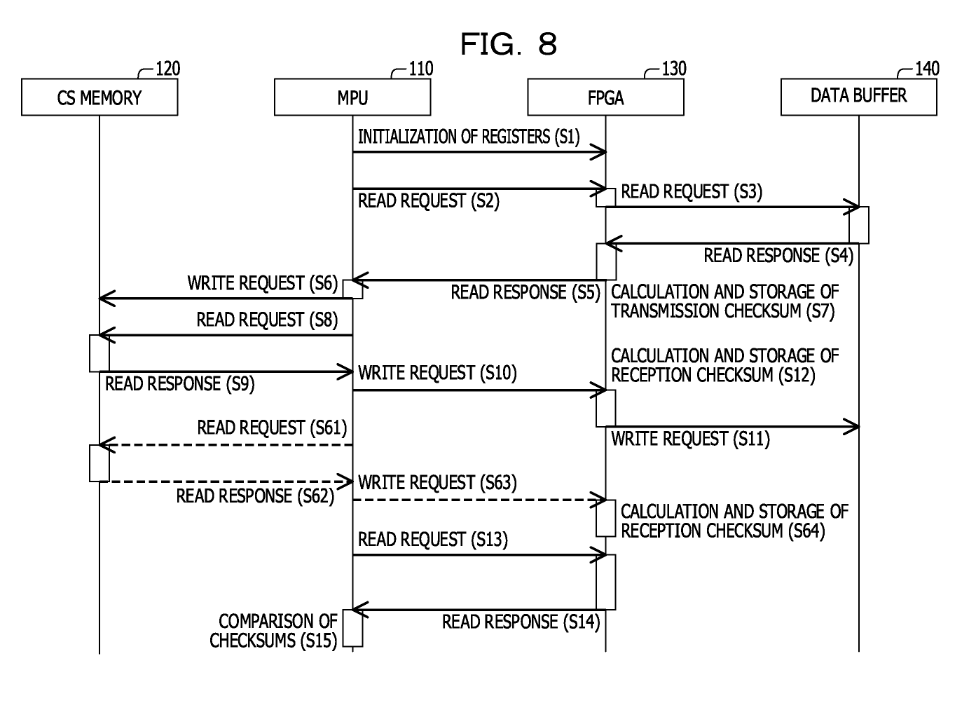

Hereinafter, an example of the data guarantee control process by the storage device according to the second modified example of the embodiment is described with reference to FIGS. 7A, 7B, 7C, and 7D and a sequence diagram (S1 to S15 and S61 to S64) of FIG. 8.

FIGS. 7A, 7B, 7C, and 7D are diagrams illustrating the example of the data guarantee control process by the storage device according to the second modified example of the embodiment. FIG. 8 is the sequence diagram of the data guarantee control process by the storage device according to the second modified example of the embodiment. Processes of S1 to S15 illustrated in FIG. 8 are the same as or similar to the processes of S1 to S15 illustrated in FIG. 3, and a detailed description thereof is omitted in some cases.

In the example of FIGS. 7A, 7B, 7C, and 7D, only the transmission checksum registers 132 and the reception checksum registers 134 are illustrated as functional configurations included in the FPGA 130, and the other functional configurations are omitted in order to simplify the illustration.

In the example illustrated in FIGS. 7A, 7B, 7C, 7D, and 8, among the data #1 to #3 transmitted by a series of I/O from the host device 3, the data #1 and #3 is valid data, and the data #2 is invalid data.

When I/O is issued by the host device 3 and the data #1 to #3 is stored in the data buffer 140, the reading and writing unit 111 of the MPU 110 clears (initializes) values stored in the transmission checksum registers 132 and reception checksum registers 134 to “0” (refer to S1 illustrated in FIG. 8).

The reading and writing unit 111 issues a request to read the data #1 to #3 stored (at, for example, the addresses 0x0000 to 0x0100) in the data buffer 140 and reads the data #1 to #3 stored in the data buffer 140 (refer to reference symbol B1 illustrated in FIG. 7A and S2 to S5 illustrated in FIG. 8).

The reading and writing unit 111 issues a write request to the CS memory 120 and writes the data #1 to #3 in the CS memory 120 (refer to S6 illustrated in FIG. 8).

The first calculator 131 of the FPGA 130 calculates checksums of the data #1 to #3 read by the MPU 110 from the data buffer 140. Then, the first calculator 131 causes the calculated checksums to be stored as transmission checksums in the transmission checksum registers 132 (refer to reference symbol B2 illustrated in FIG. 7A and S7 illustrated in FIG. 8).

The reading and writing unit 111 of the MPU 110 issues a read request to the CS memory 120 and extracts and reads the valid data #1 and #3 among the data #1 to #3 written in the CS memory 120 (refer to S8 and S9 illustrated in FIG. 8).

The reading and writing unit 111 issues a request to write the data #1 and #3 (at, for example, the addresses 0x0000 to 0x0050) in the data buffer 140 and writes the data #1 and #3 read from the CS memory 120 in the data buffer 140 (refer to reference symbol B3 illustrated in FIG. 7B and S10 and S11 illustrated in FIG. 8).

The second calculator 133 of the FPGA 130 calculates checksums of the data #1 and #3 written by the MPU 110 in the data buffer 140. Then, the second calculator 133 causes the calculated checksums to be stored as reception checksums in the reception checksum registers 134 (refer to reference symbol B4 illustrated in FIG. 7B and S12 illustrated in FIG. 8).

The reading and writing unit 111 of the MPU 110 extracts and reads the invalid data #2 among the data #1 to #3 written in the CS memory 120. Specifically, the reading and writing unit 111 issues a request to read the data #2 to the CS memory 120 (refer to S61 illustrated in FIG. 8). Then, the CS memory 120 issues a response to the reading of the data #2 to the MPU 110 (refer to S62 illustrated in FIG. 8).

The reading and writing unit 111 of the MPU 110 specifies the data buffer virtual address space (for example, virtual addresses corresponding to the physical addresses 0x8000 to 0x8050) for dummy writing to the FPGA 130 and issues a write request. Thus, the reading and writing unit 111 writes, as dummy data, the data #2 read from the CS memory 120 in the FPGA 130 (refer to reference symbol B5 illustrated in FIG. 7C and S63 illustrated in FIG. 8).

The second calculator 133 of the FPGA 130 calculates reception checksums based on the data (valid data) #1 and #3 written by the MPU 110 in the data buffer 140 and the dummy data (invalid data) #2 written by the MPU 110 in the FPGA 130. Then, the second calculator 133 causes the calculated reception checksums to be stored in the reception checksum registers 134 (refer to reference symbol B6 illustrated in FIG. 7C and S64 illustrated in FIG. 8).

An offset (for example, 0x8000) that represents dummy data is added to the data written by the MPU 110. Thus, the address converter 135 of the FPGA 130 discards the dummy data without transferring the dummy data to the data buffer 140.

The reading and writing unit 111 of the MPU 110 issues a request to read the transmission checksums and the reception checksums to the FPGA 130. Thus, the reading and writing unit 111 reads the transmission checksums stored in the transmission checksum registers 132 and the reception checksums stored in the reception checksum registers 134 (refer to reference symbol B7 illustrated in FIG. 7D and S13 and S14 illustrated in FIG. 8).

The comparator 112 of the MPU 110 compares the transmission checksums read by the reading and writing unit 111 with the reception checksums read by the reading and writing unit 111 (refer to S15 illustrated in FIG. 8).

If the transmission checksums match the reception checksums as a result of the comparison made by the comparator 112, the data #1 and #3 stored in the data buffer 140 is transmitted to the memory device 2.

On the other hand, if the transmission checksums do not match the reception checksums as a result of the comparison made by the comparator 112, the error output unit 113 of the MPU 110 outputs an error. If the transmission checksums do not match the reception checksums as a result of the comparison made by the comparator 112, the inhibitor 114 of the MPU 110 may inhibit the data #1 and #3 from being transmitted to the memory device 2.

The communication control device 1 (storage device 10) according to the second modified example of the embodiment may provide the effects described above in the example of the embodiment and the following effects, for example.

If data transmitted by the higher-level device 3 includes data that is not to be transmitted to the memory device 2, the second calculator 133 calculates a second value based on data written by the reading and writing unit 111 in the data storage unit 140 and the data that is not to be transmitted to the memory device 2. It is, therefore, possible to inhibit the comparator 112 from detecting that a transmission checksum does not match a reception checksum, regardless of the fact that an error such as garbling of data on the bus within the MPU 110 does not occur.

The reading and writing unit 111 specifies a specific address among virtual addresses and transmits, to the second calculator 133, the data that is not to be transmitted to the memory device 2. It is, therefore, possible to inhibit unwanted data from being transmitted to the memory device 2.

The technique disclosed herein is not limited to the aforementioned embodiment and may be variously modified without departing from the gist of the embodiment. At least one of the configurations according to the embodiment and at least one of the processes according to the embodiment may be selected or combined.

In the aforementioned example of the embodiment and the modified examples, the first calculator 131 and the second calculator 133 calculate checksums and the comparator 112 compares the checksums. The first calculator 131, the second calculator 133, and the comparator 112, however, are not limited to this. The first calculator 131 and the second calculator 133 may calculate various error detecting codes other than checksums, and the comparator 112 may compare the calculated error detecting codes.

In the aforementioned example of the embodiment and the modified examples, the MPU 110 have the functions as the comparator 112, the error output unit 113, and the inhibitor 114. The functions, however, are not limited to this. For example, the FPGA 130 may have the functions as the comparator 112, the error output unit 113, and the inhibitor 114.

In the aforementioned example of the embodiment and the modified examples, the reading and writing unit 111 specifies the data buffer virtual address space for dummy writing and writes dummy data in the FPGA 130. The reading and writing unit 111, however, is not limited to this. For example, the reading and writing unit 111 may specify the data buffer virtual address spaces 142 illustrated in FIG. 4 and write dummy data in the FPGA 130. In this case, before writing the dummy data, the reading and writing unit 111 transmits, to the FPGA 130, a signal representing that the dummy data is to be written. The reading and writing unit 111 may add, to the dummy data, a flag representing that the data is the dummy data, and the reading and writing unit 111 may write the dummy data in the FPGA 130. Thus, the FPGA 130 may recognize that the written data is the dummy data.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A method for detecting an error of data by a storage device including a storage configured to provide a storage region for a process by a host device and a buffer memory configured to temporarily store data that is transferred between the host device and the storage, the method comprising:
storing, by a processor that is configured to avoid adding the error correcting code to the data when the data passes through the inside of the processor, the data received from the host device and an error correcting code in the buffer memory;
reading the data from the buffer memory and transmitting the read data to a calculating circuit;
calculating, by the calculating circuit, a first checksum of the data and transmitting the data to the processor;
storing, by the processor, the data and the error correcting code in a sub memory;
reading the data from the sub memory and transmitting the read data to the calculating circuit through the processor;
calculating, by the calculating circuit, a second checksum of the data received from the sub memory and having passed through the processor; and
determining, by the processor, whether an error of the data occurs within the processor by comparing the first checksum with the second checksum.

2. The method according to claim 1, further comprising:
limiting the transmission of the data from the buffer memory to the storage, when it is determined that the error of the data occurs within the processor.

3. The method according to claim 2, further comprising:
transmitting the data stored in the buffer memory to the storage, when it is determined that the error of the data does not occur within the processor.

4. The method according to claim 1, further comprising:
specifying a virtual address and thereby reading the data stored in a storage region that is included in the buffer memory and to which a physical address corresponding to the virtual address is assigned.

5. The method according to claim 1, further comprising:
specifying a virtual address and thereby storing the data read from the sub memory in a storage region that is included in the buffer memory and to which a physical address corresponding to the virtual address is assigned.

6. The method according to claim 1,
wherein the determining includes executing a determination process for data corresponding to each of a plurality of virtual addresses assigned based on a plurality of storage regions of the buffer memory.

7. The method according to claim 1, further comprising:
causing, by the processor, the calculating circuit to hold invalid data included in the data read from the buffer memory;
extracting valid data from the data received from the calculating circuit; and
storing the valid data in the sub memory,
wherein the second checksum is calculated based on the valid data read from the sub memory and the invalid data held by the calculating circuit.

8. A storage device comprising:
a storage configured to provide a storage region for a process by a host device;
a buffer memory configured to temporarily store data that is transferred between the host device and the storage;
a calculating circuit configured to calculate a checksum of the data received from the host device;
a processor coupled to the calculating circuit and configured to avoid adding an error correcting code to the data when the data passes through the inside of the processor; and
a sub memory configured to provide a storage region for a process by the processor,
wherein the processor causes the data received from the host device and the error correcting code to be stored in the buffer memory, reads the data from the buffer memory, and transmits the read data to the calculating circuit,
wherein the calculating circuit calculates a first checksum of the data read from the buffer memory and transmits the data to the processor,
wherein the processor causes the data received from the calculating circuit and the error correcting code to be stored in the sub memory, reads the data from the sub memory, and transmits the read data to the calculating circuit so as to ensure that the data passes through the processor,
wherein the calculating circuit calculates a second checksum of the data received from the sub memory and having passed through the processor, and
wherein the processor determines whether an error of the data occurs within the processor by comparing the first checksum with the second checksum.

9. The storage device according to claim 8, wherein the processor limits the transmission of the data from the buffer memory to the storage, when it is determined that the error of the data occurs within the processor.

10. The storage device according to claim 8, wherein the processor specifies a virtual address and thereby reading the data stored in a storage region that is included in the buffer memory and to which a physical address corresponding to the virtual address is assigned.

11. The storage device according to claim 8, wherein the processor specifies a virtual address and thereby storing the data read from the sub memory in a storage region that is included in the buffer memory and to which a physical address corresponding to the virtual address is assigned.

12. A non-transitory computer-readable recording medium that causes a storage device to execute a process, the process comprising:
storing, by a processor that is configured to avoid adding the error correcting code to the data when the data passes through the inside of the processor, data received from the host device and an error correcting code in a buffer memory;
reading the data stored in the buffer memory and transmitting the read data to a calculating circuit;
calculating, by the calculating circuit, a first checksum of the data and transmitting the data to the processor;
storing, by the processor, the data and the error correcting code in a sub memory;
reading the data from the sub memory and transmitting the read data to the calculating circuit through the processor;
calculating, by the calculating circuit, a second checksum of the data received from the sub memory and having passed through the processor; and
determine, by the processor, whether an error of the data occurs within the processor by comparing the first checksum with the second checksum.
